(19) United States
(12) Patent Application Publication
(10) Pub. No.: US 2009/0166862 A1
(43) Pub. Date: Jul. 2, 2009

(54) Semiconductor device and method of manufacturing the same

(75) Inventors: Young Do Kweon, Seoul (KR); Jae Kwang Lee, Seoul (KR); Jong Hwan Baek, Seoul (KR); Hyung Jin Jeon, Gyeonggi-do (KR); Jingli Yuan, Gyeonggi-do (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon (KR)

(21) Appl. No.: 12/213,367

(22) Filed: Jun. 18, 2008

(30) Foreign Application Priority Data
Dec. 27, 2007 (KR) 10-2007-0139082

(51) Int. Cl. H01L 23/498; H01L 21/768

(52) U.S. Cl. 257/738; 438/613; 257/E23.069; 257/E21.582

(57) ABSTRACT

Provided is a semiconductor device including a wafer having an electrode pad; an insulation layer that is formed on the wafer and has an exposure hole exposing the electrode pad; a redistribution layer that is formed on the insulation layer and the exposure hole of the insulation layer and has one end connected to the electrode pad; a conductive post that is formed at the other end of the redistribution layer; an encapsulation layer that is formed on the redistribution layer and the insulation layer such that the upper end portion of the conductive post is exposed; and a solder bump that is formed on the exposed upper portion of the conducive post.

### CROSS-REFERENCE TO RELATED APPLICATIONS

This application claims the benefit of Korean Patent Application No. 10-2007-0139082 filed with the Korea Intellectual Property Office on Dec. 27, 2007, the disclosure of which is incorporated herein by reference.

### BACKGROUND OF THE INVENTION

1. Field of the Invention

The present invention relates to a semiconductor device and a method of manufacturing the same, which can minimize the damage of solder bumps caused by a difference in thermal expansion coefficient, thereby enhancing reliability.

2. Description of the Related Art

Recently, as demand for a reduction in size of electronic apparatuses is increasing, a reduction in size of semiconductor devices is required.

Therefore, chip size package (CSP) semiconductor devices are being developed and manufactured, of which the size is reduced by making the shape of the semiconductor devices approximate to that of semiconductor elements (semiconductor chips).

Hereinafter, a conventional semiconductor device will be described with reference to FIG. 1.

FIG. 1 is a cross-sectional view of a conventional semiconductor device. As shown in FIG. 1, the conventional semiconductor device includes a wafer 1 having an electrode pad 2 formed thereon, an insulation layer 3 which is formed on the wafer 1 so as to expose the electrode pad 2, a redistribution layer 4 which is formed on the insulation layer 3 and has one end connected to the electrode pad 2, a resin layer 5 which is formed on the insulation layer 3 and the redistribution layer 4 so as to expose the other end of the redistribution layer 4, a bonding assist layer 6 which is formed on the resin layer 4 and is connected to the other end of the redistribution layer 4, and a solder ball 7 which is formed on the bonding assist layer 6.

The conventional semiconductor device constructed in such a manner is manufactured by the following method.

First, the electrode pad 2 is formed on the wafer 1, and the insulation layer 3 is applied on the wafer 1.

Then, the insulation layer 3 is etched by a photolithography process such that the electrode pad 2 is exposed.

Next, a metal layer is applied onto the insulation layer 3 through a vacuum deposition process, and is then etched by the photolithography process so as to form the redistribution layer 4 which is used as a metal pattern connected to the exposed electrode pad 2 through the insulation layer 3.

Then, the resin layer 5 is applied on the insulation layer 3 and the redistribution layer 4, and is then etched by the photolithography process such that a portion of the redistribution layer 4 in the opposite side to the one end thereof, which is connected to the electrode pad 2, is exposed.

Next, a metal layer is applied onto the resin layer 4 through the vacuum deposition process, and is then etched through the photolithography process so as to form the bonding assist layer 6 which is connected to the exposed portion of the redistribution layer 4 and is used as a bonding portion on which the solder ball 7 is to be formed.

Finally, as the solder ball 7 is formed on the bonding assist layer 6 through a reflow process, the conventional semiconductor device is completely manufactured.

However, the conventional semiconductor device has the following problems.

When the conventional semiconductor device is mounted on a printed circuit board, stress concentrates on the solder ball 7 due to a difference in thermal expansion coefficient therebetween. Then, a crack 7 occurs in the solder ball 7, or the solder ball 7 is damaged.

The thermal expansion coefficient of a typical semiconductor device is about 3 ppm/k, and the thermal expansion coefficient of the printed circuit board is about 20 ppm/k, which means that a difference in thermal expansion coefficient therebetween is large. Therefore, after the semiconductor device is mounted on the printed circuit board, the semiconductor device or the printed circuit board is significantly bent by the difference in thermal expansion coefficient. Accordingly, stress concentrates on the solder ball 7 serving as a mounting medium through which the semiconductor device is mounted on the printed circuit board. Then, a crack occurs in the solder ball 7, or the solder ball 7 is damaged, thereby degrading the reliability of the semiconductor device.

Further, the manufacturing process of the conventional semiconductor device is complicated, and the manufacturing time is lengthened. Therefore, a manufacturing cost increases, and productivity is degraded.

That is, the process of etching the resin layer 5 to expose the redistribution layer 4 and the process of etching the metal layer to form the bonding assist layer 6 should be performed, in addition to the process of etching the insulation layer 4 to expose the electrode pad 2 and the process of etching the metal layer to form the redistribution layer 4. Therefore, the manufacturing process is complicated, and the manufacturing time is lengthened. Therefore, a manufacturing cost increases, and productivity is degraded.

### SUMMARY OF THE INVENTION

An advantage of the present invention is that it provides a semiconductor device and a method of manufacturing the same, which can minimize the damage of solder bumps caused by a difference in thermal expansion coefficient, thereby enhancing reliability.

Additional aspects and advantages of the present general inventive concept will be set forth in part in the description which follows and, in part, will be obvious from the description, or may be learned by practice of the general inventive concept.

According to an aspect of the invention, a semiconductor device comprises a wafer having an electrode pad; an insulation layer that is formed on the wafer and has an exposure hole exposing the electrode pad; a redistribution layer that is formed on the insulation layer and the exposure hole of the insulation layer and has one end connected to the electrode pad; a conductive post that is formed at the other end of the redistribution layer; an encapsulation layer that is formed on the redistribution layer and the insulation layer such that the upper end portion of the conductive post is exposed; and a solder bump that is formed on the exposed upper portion of the conducive post.

The conductive post may be formed of conductive polymer.

Preferably, the conductive post is formed by stencil printing or screen printing.

The lower end portion of the solder bump may be formed to extend to the inside of the upper end portion of the conductive post.

According to another aspect of the invention, a method of manufacturing a semiconductor device comprises the steps of: forming an insulation layer on a wafer such that an electrode pad is exposed; forming a redistribution layer on the insulation layer such that the redistribution layer is connected to the electrode pad; forming a conductive post on the redistribution layer; forming an encapsulation layer on the redistribution layer and the insulation layer; and forming a solder bump on the conductive post.

The conductive post may be formed of conductive polymer.

Preferably, the conductive post is formed by stencil printing or screen printing.

The encapsulation layer may be formed in such a manner that the upper end portion of the conductive post is exposed.

The lower end portion of the solder bump may be formed to extend to the inside of the upper end portion of the conductive post.

According to a further aspect of the invention, a semiconductor device comprises a wafer having an electrode pad; an insulation layer that is formed on the wafer and has an exposure hole exposing the electrode pad; a redistribution layer that is formed on the insulation layer and the exposure hole of the insulation layer and has one end connected to the electrode pad; a conductive polymer post that is formed at the other end of the redistribution layer; a plurality of solder bumps that are stacked on the top surface of the conductive polymer posts; an encapsulation layer that is formed on the redistribution layer and the insulation layer such that the upper end portion of the uppermost solder bump among the plurality of solder bumps is exposed; and a further solder bump that is formed on the exposed upper portion of the uppermost solder bump.

According to a still further aspect of the invention, a method of manufacturing a semiconductor device comprises the steps of: forming an insulation layer on a wafer such that an electrode pad is exposed; forming a redistribution layer on the insulation layer such that the redistribution layer is connected to the electrode pad; forming a conductive polymer post on the redistribution layer; stacking a plurality of solder bumps on the top surface of the conductive polymer post; forming an encapsulation layer on the redistribution layer and the insulation layer such that the upper end portion of the uppermost solder bump among the solder bumps is exposed; and forming a further solder bump on the exposed upper portion of the uppermost solder bump.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a cross-sectional view of a conventional semiconductor device;

FIG. 2 is a cross-sectional view of a semiconductor device according to a first embodiment of the invention;

FIGS. 3 to 8 are process diagrams sequentially showing a method of manufacturing the semiconductor device according to the first embodiment of the invention; and

FIG. 9 is a cross-sectional view of a semiconductor device according to a second embodiment of the invention.

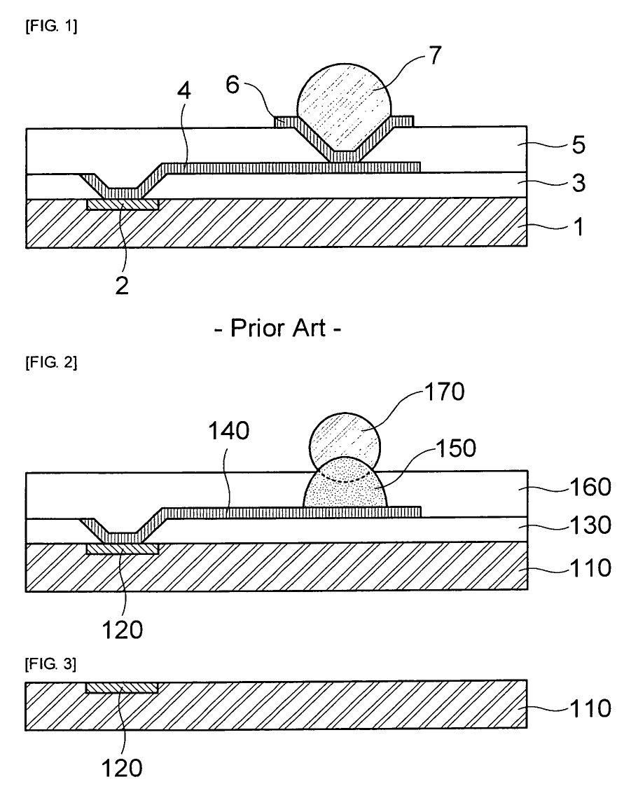

### DETAILED DESCRIPTION OF THE PREFERRED EMBODIMENTS

Reference will now be made in detail to the embodiments of the present general inventive concept, examples of which are illustrated in the accompanying drawings, wherein like reference numerals refer to like elements throughout. The embodiments are described below in order to explain the present general inventive concept by referring to the figures.

Hereinafter, a semiconductor device and a method of manufacturing the same according to the present invention will be described in detail with reference to the accompanying drawings.

Semiconductor device according to first embodiment

Referring to FIG. 2, a semiconductor device according to a first embodiment of the invention will be described.

FIG. 2 is a cross-sectional view of a semiconductor device according to a first embodiment of the invention.

As shown in FIG. 2, the semiconductor device according to the first embodiment of the invention includes a wafer 110 having an electrode pad 120 formed thereon, an insulation layer 130 which is formed on the top surface of the wafer 110 and has an exposure hole 131 exposing the electrode pad 120, a redistribution layer 140 which is formed on the insulation layer 130 and the expose hole 131 of the insulation layer 130 and has one end connected to the electrode pad 120, a conductive post 150 formed at the other end of the redistribution layer 140, an encapsulation layer 160 which is formed on the redistribution layer 140 and the insulation layer 130 such that the upper end portion of the conductive post 150 is exposed, and a solder bump 170 formed on the exposed upper end portion of the conductive post 150.

The conductive post 150 may be formed of a conductive polymer post.

Preferably, the conductive post 150 is formed by a printing method such as stencil printing or screen printing.

That is, as the conductive post 150 is formed at the other end of the redistribution layer 140, which is exposed, by the stencil printing or screen printing process, a photolithography process for forming a space in which a bonding assist layer for connecting a redistribution layer and a solder ball is to be formed and a photolithograph process for forming the bonding assist layer can be omitted. Therefore, the manufacturing process can be simplified, and the manufacturing time can be shortened, which makes it possible to reduce a manufacturing cost and to enhance productivity.

Further, since the conductive post 150 is formed of conductive polymer and is surrounded by the encapsulation layer 160 except for the upper end portion of the conductive post 150 to which the solder bump 170 is bonded, stress concentrating on the solder bump 170 is distributed and buffered by the conductive post 150. Therefore, crack or damage occurring in the solder bump 170 can be minimized, which makes it possible to enhance the reliability of the semiconductor device.

The lower end of the solder bump 170 may be formed to extend to the inside of the upper end portion of the conductive post 150.

Therefore, the bonding property of the solder bump 170 is enhanced so that the crack or damage of the solder bump 170 caused by an external force is minimized, which makes it possible to enhance the reliability of the semiconductor device including the solder bump 170.

### Method of Manufacturing Semiconductor Device According to First Embodiment

Referring to FIGS. 3 to 8, a method of manufacturing the semiconductor device according to the first embodiment of the invention will be described.

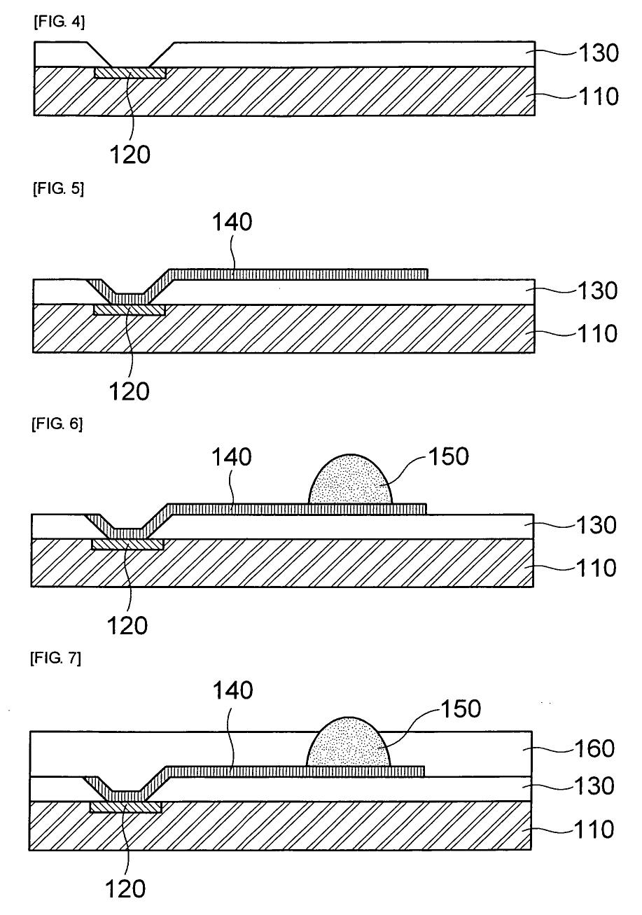

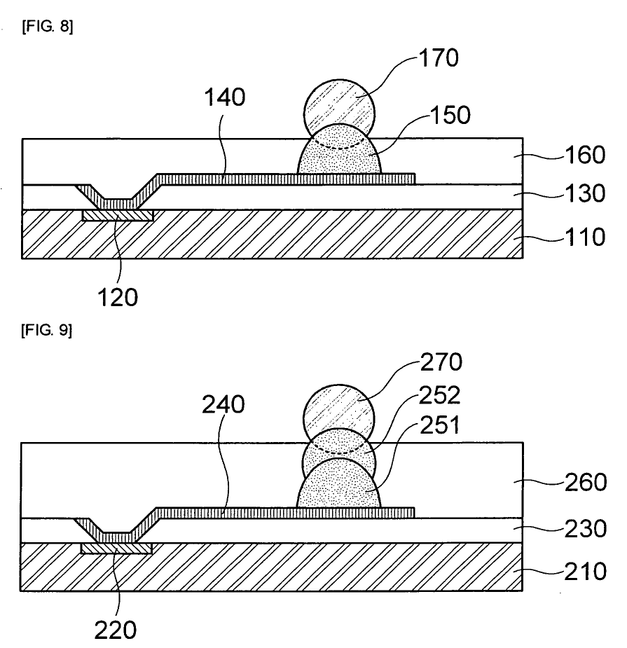

FIGS. 3 to 8 are process diagrams sequentially showing a method of manufacturing the semiconductor device according to the first embodiment of the invention. FIG. 3 is a cross-sectional view showing a state where the electrode pad is formed on the wafer. FIG. 4 is a cross-sectional view showing a state where the insulation layer is formed. FIG. 5 is a cross-sectional view showing a state where the redistribution layer is formed. FIG. 6 is a cross-sectional view showing a state where the conductive post is formed. FIG. 7 is a cross-sectional view showing a state where the encapsulation layer is formed. FIG. 8 is a cross-sectional view showing a state where the solder bump is formed.

First, as shown in FIG. 3, the electrode pad 120 is formed on the wafer 110.

Then, as shown in FIG. 4, the insulation layer 130 is applied on the wafer 110, and is then etched by a photolithography process such that the electrode pad 120 is exposed.

Next, as shown in FIG. 5, a metal layer is applied on the insulation layer 130, and is then etched by the photolithography process so as to form the redistribution layer 140 which is used as a metal pattern connected to the electrode pad 120 exposed through the insulation layer 130.

Then, as shown in FIG. 6, the conductive post 150 is formed by stencil-printing or screen-printing conductive polymer on the opposite side to one side of the redistribution layer 140, which is connected to the electrode pad 120.

Next, as shown in FIG. 7, the encapsulation layer 160 is formed on the redistribution layer 140 and the insulation layer 130 such that the upper end portion of the conductive post 150 is exposed.

At this time, the encapsulation layer 160 may be formed by applying epoxy resin on the redistribution layer 140 and the insulation layer 130 such that the upper end portion of the conductive post 150 is exposed.

Finally, as the solder bump 170 is formed on the exposed upper end portion of the conductive post 150, the semiconductor device according to the first embodiment of the invention is completely manufactured.

Preferably, the lower end portion of the solder bump 170 may be formed to extend to the inside of the upper end portion of the conductive post 150.

### Semiconductor Device According to Second Embodiment

Referring to FIG. 9, a semiconductor device according to a second embodiment of the invention will be described.

FIG. 9 is a cross-sectional view of a semiconductor device according to a second embodiment of the invention.

As shown in FIG. 9, the semiconductor device according to the second embodiment of the invention includes a wafer 210 having an electrode pad 220 formed thereon, an insulation layer 230 which exposes the electrode pad 220, a redistribution layer 240 connected to the electrode pad 220, a plurality of conductive polymer posts 251 and 252 formed on the redistribution layer 240, an encapsulation layer 260 which is formed in such a manner that the upper end portion of the conductive polymer posts 251 and 252 are exposed, and a solder bump 270 which is formed on the exposed upper end portion of the conductive polymer posts 251 and 252.

Unlike the first embodiment, the semiconductor device according to the second embodiment of the invention has the plurality of conductive polymer posts 251 and 252 formed on the redistribution layer 240.

That is, the conductive polymer posts 251 and 252 of the semiconductor device according to the second embodiment of the invention are composed of the lowermost conductive polymer post 251 formed on the redistribution layer 240 and the uppermost conductive polymer post 252 stacked on the lowermost conductive polymer post 252.

Preferably, the encapsulation layer 260 is formed in such a manner that the upper end portion of the uppermost conductive polymer post 252 is exposed.

Further, the solder bump 270 is formed on the uppermost conductive polymer post 252.

Preferably, the plurality of conductive polymer posts 251 and 252 are also formed by a stencil printing or screen printing process.

As the plurality of conductive polymer posts 251 and 252 are formed in the semiconductor device according to the second embodiment of the invention, a lead distance between the solder bump 270 and the redistribution layer 240 is further lengthened, thereby further enhancing an effect of distributing stress concentrating on the solder bump 270. Therefore, it is possible to enhance the reliability of the semiconductor device.

Between the plurality of conductive polymer posts 251 and 252 in the semiconductor device according to the second embodiment of the invention, the uppermost conductive polymer post 252 may be formed of a conductive metallic material similar to the solder bump 270.

That is, after a solder bump is formed on the lowermost polymer post 251 formed on the redistribution layer 240, the encapsulation layer 260 may be formed in such a manner that the upper end portion of the solder bump formed on the lowermost polymer post 251 is exposed, and the solder bump 270 may be then formed on the exposed upper portion of the solder bump.

Further, a plurality of solder bumps may be stacked on the lowermost conductive polymer post 251. In this case, after the encapsulation layer is formed in such a manner that only the upper end portion of a solder bump positioned in the uppermost portion is exposed, a solder bump may be further formed on the exposed upper portion of the solder bump positioned in the uppermost portion.

According to the present invention, stress concentrating on the solder bump when the semiconductor device is mounted is distributed to thereby minimize the crack or damage caused by a difference in thermal expansion coefficient. Therefore, it is possible to enhance the reliability of the semiconductor device.

Further, the manufacturing process can be simplified, which makes it possible to reduce a manufacturing cost and to enhance productivity of the semiconductor device.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

1. A semiconductor device comprising:
a wafer having an electrode pad;
an insulation layer that is formed on the wafer and has an exposure hole exposing the electrode pad;
a redistribution layer that is formed on the insulation layer and the exposure hole of the insulation layer and has one end connected to the electrode pad;
a conductive post that is formed at the other end of the redistribution layer;
an encapsulation layer that is formed on the redistribution layer and the insulation layer such that the upper end portion of the conductive post is exposed; and
a solder bump that is formed on the exposed upper portion of the conductive post.

2. The semiconductor device according to claim 1, wherein the conductive post is formed of conductive polymer.

3. The semiconductor device according to claim 1, wherein the conductive post is formed by stencil printing or screen printing.

4. The semiconductor device according to claim 1, wherein the lower end portion of the solder bump is formed to extend to the inside of the upper end portion of the conductive post.

5. A method of manufacturing a semiconductor device comprising:
forming an insulation layer on a wafer such that an electrode pad is exposed;
forming a redistribution layer on the insulation layer such that the redistribution layer is connected to the electrode pad;
forming a conductive post on the redistribution layer;
forming an encapsulation layer on the redistribution layer and the insulation layer; and
forming a solder bump on the conductive post.

6. The method according to claim 5, wherein the conductive post is formed of conductive polymer.

7. The method according to claim 5, wherein the conductive post is formed by stencil printing or screen printing.

8. The method according to claim 5, wherein the encapsulation layer is formed in such a manner that the upper end portion of the conductive post is exposed.

9. The method according to claim 5, wherein the lower end portion of the solder bump is formed to extend to the inside of the upper end portion of the conductive post.

10. A semiconductor device comprising:
a wafer having an electrode pad;
an insulation layer that is formed on the wafer and has an exposure hole exposing the electrode pad;
a redistribution layer that is formed on the insulation layer and the exposure hole of the insulation layer and has one end connected to the electrode pad;
a conductive polymer post that is formed at the other end of the redistribution layer;
a plurality of solder bumps that are stacked on the top surface of the conductive polymer posts;
an encapsulation layer that is formed on the redistribution layer and the insulation layer such that the upper end portion of the uppermost solder bump among the plurality of solder bumps is exposed; and
a further solder bump that is formed on the exposed upper portion of the uppermost solder bump.

11. A method of manufacturing a semiconductor device comprising:
forming an insulation layer on a wafer such that an electrode pad is exposed;
forming a redistribution layer on the insulation layer such that the redistribution layer is connected to the electrode pad;
forming a conductive polymer post on the redistribution layer;
stacking a plurality of solder bumps on the top surface of the conductive polymer post;
forming an encapsulation layer on the redistribution layer and the insulation layer such that the upper end portion of the uppermost solder bump among the solder bumps is exposed; and
forming a further solder bump on the exposed upper portion of the uppermost solder bump.
